(19) United States
(12) Patent Application Publication
(10) Pub. No.: US 2018/0083178 A1
(43) Pub. Date: Mar. 22, 2018

(54) THERMOELECTRIC MATERIAL, METHOD FOR FABRICATING THE SAME, AND THERMOELECTRIC ELEMENT USING THE SAME

(71) Applicant: ELECTRONICS AND TELECOMMUNICATIONS RESEARCH INSTITUTE, Daejeon (KR)

(72) Inventors: Seungeon MOON, Daejeon (KR); Junsoo KIM, Daejeon (KR); SEUNG MIN LEE, Suwon-si (KR)

(73) Assignee: ELECTRONICS AND TELECOMMUNICATIONS RESEARCH INSTITUTE, Daejeon (KR)

(21) Appl. No.: 15/822,736

(22) Filed: Nov. 27, 2017

Related U.S. Application Data
(62) Division of application No. 15/267,128, filed on Sep. 15, 2016.

(30) Foreign Application Priority Data
Sep. 16, 2015 (KR) 10-2015-0131093
Apr. 12, 2016 (KR) 10-2016-0045083

(51) Int. Cl. H01L 35/22; H01L 35/34

(52) U.S. Cl. CPC H01L 35/22; H01L 35/34

(57) ABSTRACT

Provided is a thermoelectric material including a metal silicide film, and silicon particles dispersed in the metal silicide film, the total volume of the silicon particles being greater than the volume of the metal silicide film.

### CROSS-REFERENCE TO RELATED APPLICATIONS

This application is a divisional of U.S. application Ser. No. 15/267,128, filed on Sep. 15, 2016. Further, this U.S. non-provisional patent application claims priority under 35 U.S.C. § 119 of Korean Patent Application Nos. 10-2015-0131093, filed on Sep. 16, 2015, and 10-2016-0045083, filed on Apr. 12, 2016, the entire contents of which are hereby incorporated by reference.

### BACKGROUND

The present disclosure relates to a thermoelectric material, a method for manufacturing the same, and a thermoelectric element using the same, and more particularly, to a thermoelectric material having enhanced thermoelectric performance, a method for manufacturing the same, and a thermoelectric material using the same.

Thermoelectric elements are elements used for direct conversion of thermal energy to electrical energy, or electrical energy to thermal energy. The Seebeck effect, in which an electromotive force is generated due to a temperature difference, and the Peltier effect, in which a temperature difference between two ends is generated due to an externally applied electromotive force, are commonly used. Various thermoelectric materials are being researched with regard to application in thermoelectric generation or in cooling elements.

The performance of a thermoelectric material is indicated, as follows, by the value of a thermoelectric figure of merit (ZT).

ZT=S²σT/κ

(ZT: thermoelectric figure of merit, S: Seebeck coefficient, σ: electrical conductivity, T: absolute temperature, κ: thermal conductivity)

### SUMMARY

An objective of the present invention is to provide a thermoelectric material having enhanced thermoelectric performance.

An objective of the present invention is to provide a less expensive thermoelectric material.

An objective of the present invention is to provide an environmentally friendly thermoelectric material.

However, objectives of the present invention are not limited to those described above.

An embodiment of the inventive concept provides a thermoelectric material including a metal silicide film; and silicon particles dispersed in the metal silicide film, wherein the total volume of the silicon particles may be greater than the total volume of the metal silicide film.

In an embodiment, the silicon particles may be in the form of a crystalline nanopowder.

In an embodiment, the particle diameter of each of the silicon particles may be about 1 nanometer (nm) to about 100 nanometers (nm).

In an embodiment, at least a portion of the silicon particles may be spaced apart from each other.

In an embodiment, directly adjacent silicon particles among the silicon particles may be spaced apart about 1 nanometer (nm) to about 100 nanometers (nm).

In an embodiment, the thickness of the metal silicide film interposed between directly adjacent silicon particles among the silicon particles may be about 1 nanometer (nm) to about 100 nanometers (nm).

In an embodiment, the metal silicide film may contain at least one of platinum monosilicide (PtSi), titanium disilicide (TiSi₂), dicobalt silicide (Co₂Si), cobalt monosilicide (CoSi), cobalt disilicide (CoSi₂), nickel monosilicide (NiSi), nickel disilicide (NiSi₂), tungsten disilicide (WSi₂), molybdenum disilicide (MoSi₂), tantalum disilicide (TaSi₂), manganese silicides (MnSix), iron disilicide (FeSi₂), ruthenium sesquisilicide (Ru₂Si₃), Mg₂(Si, Sn), erbium monosilicide (ErSi), gold silicide (AuSi), or silver silicide (AgSi).

In an embodiment, at least a portion of the silicon particles may be in contact with each other.

In an embodiment of the inventive concept, a method for manufacturing a thermoelectric material includes mixing a silicon powder with a metal precursor solution to thereby form a preliminary thermoelectric material mixed solution; and sintering the preliminary thermoelectric material mixed solution to thereby form a thermoelectric material, wherein the mass of the silicon powder may be about 2 to 10⁴ times that of the metal precursor solution.

In an embodiment, the preliminary thermoelectric material mixed solution may further contain impurity particles.

In an embodiment, the sintering operation may be performed by using a spark plasma sintering method, the temperature of the spark plasma sintering operation being about 200° C. to about 600° C., and the spark plasma sintering being performed for about 1 minute to about 30 minutes.

In an embodiment, the metal precursor solution may contain a metal precursor and a solvent, the solvent being removed through the sintering operation, and the metal precursor being transformed into a metal silicide film through the sintering operation.

In an embodiment, the thermoelectric material contains a metal silicide film and the silicon powder dispersed in the metal silicide film, the volume of the metal silicide film in the thermoelectric material being smaller than the volume of the silicon powder.

In an embodiment of the inventive concept, a thermoelectric element includes a first thermoelectric material unit having a first conductivity type; a second thermoelectric material unit having a second conductivity type that is different from the first conductivity type; a first conductor contacting the top face of the first thermoelectric material unit and the top face of the second thermoelectric material unit; and a pair of second conductors respectively contacting the bottom face of the first thermoelectric material unit and the bottom face of the second thermoelectric material unit, wherein each of the first thermoelectric material unit and the second thermoelectric material unit may contain a metal silicide film and silicon particles dispersed in the metal silicide film, the total volume of the silicon particles being greater than the volume of the metal silicide film in each of the first thermoelectric material unit and the second thermoelectric material unit.

### BRIEF DESCRIPTION OF THE FIGURES

FIG. 1 is a perspective view illustrating a thermoelectric material according to an embodiment of the inventive concept;

FIG. 2 is an expanded view of area A in FIG. 1 illustrating a thermoelectric material according to an embodiment of the inventive concept;

FIG. 3 is a flow chart for illustrating a method for manufacturing a thermoelectric material according to an embodiment of the inventive concept;

FIG. 4 is a conceptual diagram illustrating a thermoelectric device according to an embodiment of the inventive concept; and

FIG. 5 is a conceptual diagram illustrating a thermoelectric device according to an embodiment of the inventive concept.

### DETAILED DESCRIPTION

Exemplary embodiments of the present invention are described with reference to the accompanying drawings in order to more effectively describe the features and effects of the present invention. However, the present invention is not limited to the embodiments described below and may be realized in various configurations and modified in various ways. The embodiments provide a more complete description of the present invention and are provided so that a person skilled in the art may better understand the scope of the invention.

Throughout the disclosure, like reference numerals refer to like elements. Embodiments described herein will be explained with reference to idealized, exemplary cross-sectional diagrams of the inventive concept. In the drawings, the thicknesses of regions are exaggerated for effective description of the technical contents. Thus, regions illustrated in the drawings are schematic in nature and the shapes thereof are for exemplifying the shapes of particular regions in the device and do not limit the scope of the invention. Various terms are used to describe the various elements of the various embodiment disclosed herein, but these elements are not limited by such terms. Such terms are only used to distinguish one element from another element. Embodiments described herein also include complementary embodiments thereof.

The terminology used herein is for the purpose of describing particular embodiments only and is not intended to be limiting of the invention. As used herein, singular forms are intended to include the plural forms as well, unless the context clearly indicates otherwise. The terms “comprise” and/or “comprising”, when used in this specification, specify the presence of stated elements, but do not preclude the presence or addition of one or more other elements.

Hereinafter, the present invention will be explained in detail by describing exemplary embodiments of the inventive concept, with reference to the accompanying drawings.

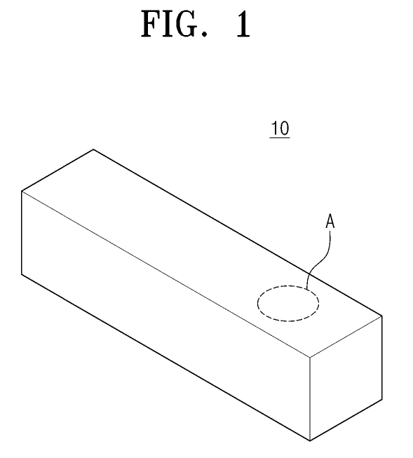

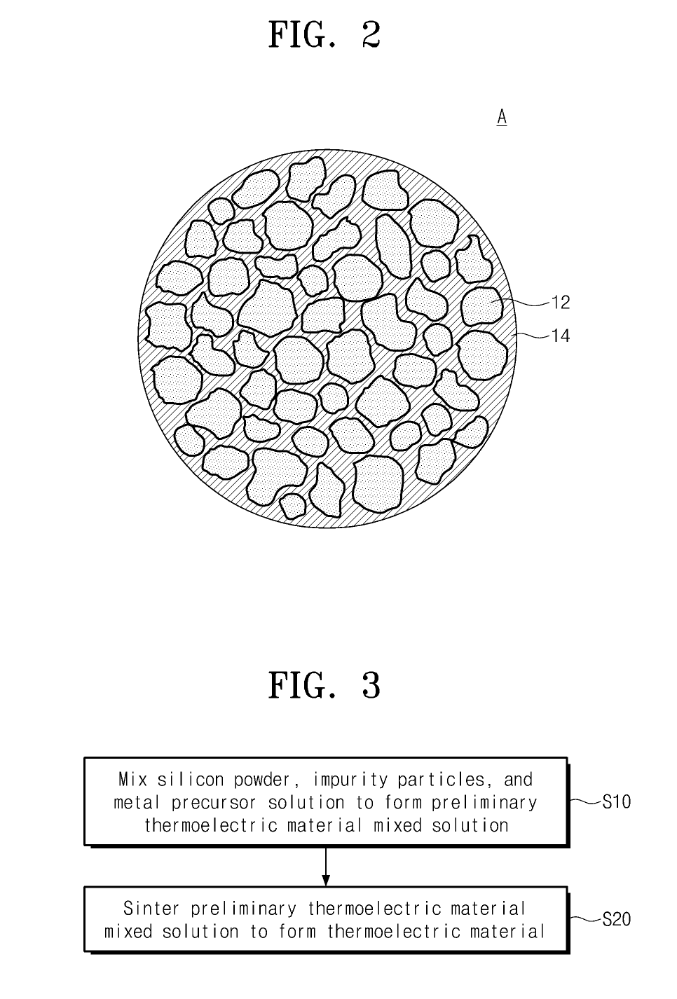

FIG. 1 is a perspective view of a thermoelectric material according to an embodiment of the inventive concept. FIG. 2 is an expanded view of area A in FIG. 1.

Referring to FIG. 1, a thermoelectric material 10 may be provided. The thermoelectric material 10 may be used to generate the Peltier effect or the Seebeck effect. The thermoelectric material 10 may have various shapes as needed. For example, as illustrated in FIG. 1, the thermoelectric material 10 may be in the shape of a hexahedron.

Referring to FIG. 2, the thermoelectric material 10 may contain a metal silicide film 14 and silicon particles 12 dispersed in the metal silicide film 14. The metal silicide film 14 may contain metal elements having a high electrical conductivity. For example, the metal silicide film 14 may include at least one of platinum monosilicide (PtSi), titanium disilicide (TiSi₂), dicobalt silicide (Co₂Si), cobalt monosilicide (CoSi), cobalt disilicide (CoSi₂), nickel monosilicide (NiSi), nickel disilicide (NiSi₂), tungsten disilicide (WSi₂), molybdenum disilicide (MoSi₂), tantalum disilicide (TaSi₂), manganese silicides (MnSix), iron disilicide (FeSi₂), ruthenium sesquisilicide (Ru₂Si₃), Mg₂(Si, Sn), erbium monosilicide (ErSi), gold silicide (AuSi), or silver silicide (AgSi). In the thermoelectric material 10, the volume of the metal silicide film 14 may be smaller than the total volume of the silicon particles 12. The thickness of the metal silicide film 14 interposed between the silicon particles 12 that are directly adjacent to each other may be about several nanometers (nm) to about several hundred nanometers (nm). Here, the thickness of the metal silicide film 14 may correspond to the distance of the spacing between the silicon particles 12 that are directly adjacent to each other. For example, the thickness of the metal silicide film 14 interposed between the silicon particles 12 that are directly adjacent to each other may be about 1 nanometer (nm) to about 100 nanometers (nm).

Each of the silicon particles 12 may be surrounded by the metal silicide film 14. The particle diameter of each of the silicon particles 12 may be about several nanometers (nm) to about several hundred nanometers (nm). For example, the particle diameter of the silicon particles 12 may be about 1 nanometer (nm) to about 100 nanometers (nm). In an embodiment, a portion of the silicon particles 12 may be in contact with each other, and another portion may be spaced apart from each other. Among the silicon particles 12 that are spaced apart from each other, the silicon particles 12 that are directly adjacent to each other may be spaced apart by about several nanometers (nm) to about several hundred nanometers (nm). For example, the silicon particles 12 that are directly adjacent to each other may be spaced apart by about 1 nanometer (nm) to about 100 nanometers (nm). The silicon particles 12 may be in the form of a crystalline nanopowder. That is, the silicon particles 12 may be a single-crystalline silicon nanopowder or a polysilicon nanopowder. The silicon particles 12 may have n-type or p-type conductivity. For example, each of the silicon particles 12 may contain therein group five elements, such as phosphorus (P) or arsenic (As), and thus have n-type conductivity. For example, each of the silicon particles 12 may contain therein group three elements, such as aluminum (Al) or boron (B), and thus have p-type conductivity.

According to an embodiment of the inventive concept, the thermoelectric material having a high thermoelectric figure of merit may be provided. Specifically, the thermoelectric figure of merit of the thermoelectric material may be increased by minimizing the thermal conductivity and maximizing the electrical conductivity. For example, the thermal conductivity may be minimized by the occurrence of phonon scattering between the silicon particles 12 and the metal silicide film 14. Since the metal silicide film 14 has a low electrical resistivity, the electrical conductivity of the thermoelectric material may be maximized.

Hereinafter, description is given of a method for manufacturing a thermoelectric material according to an embodiment of the inventive concept.

FIG. 3 is a flow chart for illustrating a method for manufacturing a thermoelectric material according to an embodiment of the inventive concept. For conciseness of description, explanations substantially identical to those given with reference to FIGS. 1 and 2 may be excluded.

Referring to FIG. 3, silicon particles, impurity particles, and a metal precursor solution may be mixed to form a preliminary thermoelectric material mixed solution S10. The preliminary thermoelectric material mixed solution may contain the silicon particles and impurity particles dispersed in the metal precursor solution. The silicon particles may be prepared through physical methods or chemical methods. Physical methods for preparing the silicon particles may include mechanical milling in which a bulk is milled into small particles. Chemical methods for preparing the silicon particles may include one of solid phase synthesis, liquid state synthesis, or chemical vapor synthesis. In an embodiment, the silicon particles may be formed through a thermal plasma method, which is a type of chemical vapor synthesis. The thermal plasma method may be a method which uses a heat source, in which the heat source is formed by a high temperature plasma. For example, a silicon gas may be formed by passing a silicon precursor through the heat source. The silicon gas may be collected and cooled to thereby form the crystalline silicon particles.

The silicon particles may be crushed. The crushing operation of the silicon particles may be performed using a mechanical crushing method. The mechanical crushing method may include a milling operation. The milling operation may include at least one of vibratory ball milling, rotary ball milling, planetary ball milling, attrition milling, specs milling, jet milling, or bulk mechanical alloying. In an example, when jet milling is used, the silicon particles may be crushed through an operation in which the silicon particles are discharged from a nozzle and collide with each other. In another example, when rotary ball milling is used, the silicon particles may be crushed through an operation in which, after the silicon particles and steel balls are placed in a jar, the jar is rotated. The silicon particles may be in the form of a crystalline nanopowder. The nanopowder may be defined as a powder having an average particle diameter of about several nanometers (nm) to about several hundred nanometers (nm). Accordingly, the particle diameter of each of the silicon particles may be about several nanometers (nm) to about several hundred nanometers (nm). For example, the particle diameter of each of the silicon particles may be about 1 nanometer (nm) to about 100 nanometers (nm).

The impurity particles may be determined according to the conductivity type required by the thermoelectric material. For example, when the thermoelectric material is an n-type semiconductor, the impurity particles may include phosphorus (P) or arsenic (As). When the thermoelectric material is a p-type semiconductor, the impurity particles may include boron (B) or aluminum (Al). The impurity particles may be crushed into the shape of a nanopowder. The crushing operation of the impurity particles may be substantially the same as the crushing operation of the silicon particles. In an embodiment, the impurity particles may be crushed together with the silicon particles. In the preliminary thermoelectric material mixed solution, the mass of the impurity particles may be smaller than the mass of the silicon particles. For example, the mass of the impurity particles may be about 10⁻⁴ to about 0.5 times the mass of the silicon particles.

The metal precursor solution may be formed by dissolving a precursor of the metal in a solvent. The metal precursor may contain a metal substance. For example, the metal in the metal precursor may include at least one of platinum (Pt), titanium (Ti), cobalt (Co), nickel (Ni), tungsten (W), molybdenum (Mo), tantalum (Ta), manganese (Mn), iron (Fe) rubidium (Ru), magnesium (Mg), gold (Au), silver (Ag), or erbium (Er). In the preliminary thermoelectric material mixed solution, the mass of the metal precursor solution may be smaller than the mass of the silicon particles. For example, the mass of the metal precursor solution may be about 10⁻⁴ to about 0.5 times the mass of the silicon particles.

The preliminary thermoelectric material mixed solution may be sintered to form a thermoelectric material S20. For example, the sintering operation of the preliminary thermoelectric material mixed solution may include at least one of hot pressing or spark plasma sintering. When spark plasma sintering is used, the preliminary thermoelectric material mixed solution may be sintered in a mold. Specifically, the preliminary thermoelectric material mixed solution provided in the mold may be sintered by being plasma treated in a plasma gas atmosphere. The plasma gas may include at least one of argon gas (Ar) or hydrogen gas (H₂). The spark plasma sintering operation may be performed at about 200° C. to about 600° C. for about 1 minute to about 30 minutes. Through the sintering operation, the solvent in the metal precursor solution may be removed and the metal precursor may be transformed into a metal silicide film. Specifically, portions of the metal precursor solution other than the metal substance may be removed to form a metal film. The metal film may contact the silicon particles and thereby react with the silicon particles. Consequently, the metal film may be transformed into a metal silicide film. Through the sintering operation, a thermoelectric material including the metal silicide film and the silicon particles dispersed in the metal silicide film may be formed. Here, the silicon particles may contain therein the impurity particles.

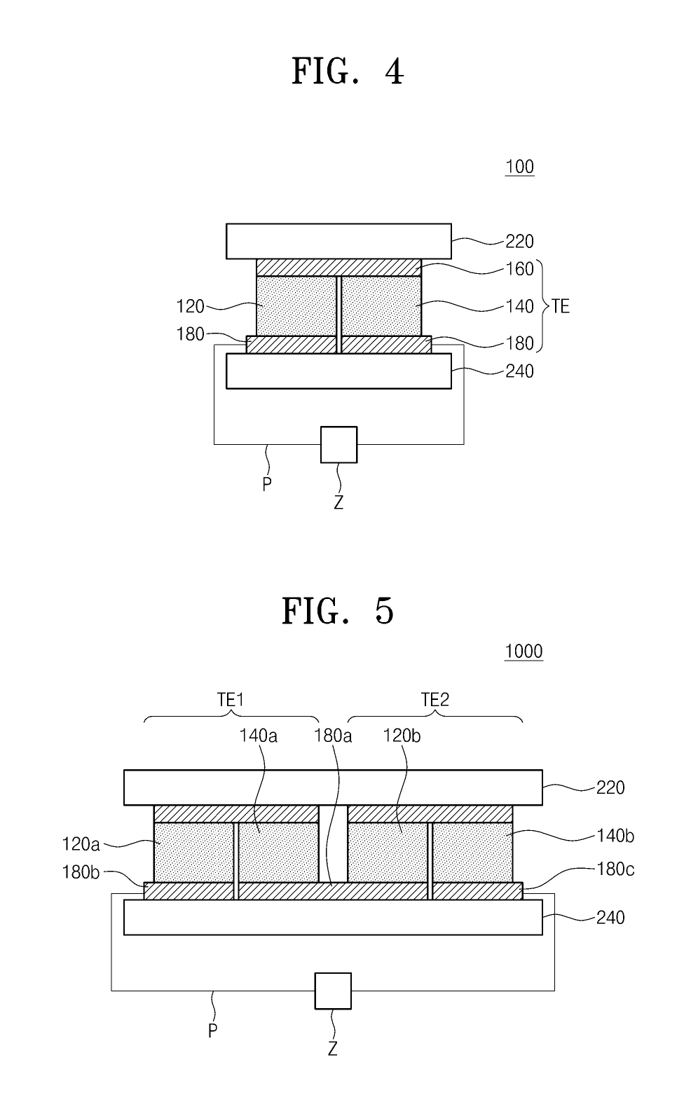

FIG. 4 is a conceptual diagram illustrating a thermoelectric device according to an embodiment of the inventive concept. For conciseness of description, explanations substantially identical to those given with reference to FIGS. 1 and 2 may be excluded.

Referring to FIG. 4, a thermoelectric device 100 may be provided. The thermoelectric device 100 may be a device capable of converting thermal energy into electrical energy or electrical energy into thermal energy. The thermoelectric device 100 may include a first thermoelectric material unit 120 and a second thermoelectric material unit 120 which are spaced apart from each other. The first and second thermoelectric material units 120 and 140 may be substantially identical to the thermoelectric material described with reference to FIGS. 1 and 2. Silicon particles (not shown) in the first thermoelectric material unit 120 may have a first conductivity type. Silicon particles (not shown) in the second thermoelectric material unit 140 may have a second conductivity type that is different from the first conductivity type. For example, the first conductivity type may be n-type conductivity, and the second conductivity type may be p-type conductivity. When the first conductivity type is n-type conductivity, the first thermoelectric material unit 120 may contain group five elements such as phosphorus (P) or arsenic (As), and the second thermoelectric material unit 140 may contain group three elements such as aluminum (Al) or boron (B).

A first conductive film 160 may be provided on the first and second thermoelectric material units 120 and 140. The first conductive film 160 may contain a metal. For example, the first conductive film 160 may contain at least one of iron (Fe), aluminum (Al), or copper (Cu). A portion of the first conductive film 160 may contact the top face of the first thermoelectric material unit 120, and another portion may contact the top face of the second thermoelectric material unit 140. Consequently, the first thermoelectric material unit 120, the first conductive film 160, and the second thermoelectric material unit 140 may be electrically connected.

A pair of second conductive films 180 which are spaced apart from each other may be provided below the first and second thermoelectric material units 120 and 140. The pair of second conductive films 180 may respectively contact the bottom face of the first thermoelectric material unit 120 and the bottom face of the second thermoelectric material unit 140. The pair of second conductive films 180 may contain a metal. For example, the pair of second conductive films 180 may contain at least one of iron (Fe), aluminum (Al), or copper (Cu). The first and second thermoelectric material units 120 and 140, the first conductive film 160, and the pair of second conductive films 180 may be defined as a thermoelectric element TE. The pair of second conductive films 180 may be connected to an electrical device Z through an electrical pathway P. For example, the electrical pathway P may be a conducting wire.

A high temperature contact part 220 may be provided on the first conductive film 160. One face of the high temperature contact part 220 may contact the first conductive film 160 and the other face may contact a heat source (not shown). The high temperature contact part 220 may contain a thermally conductive material (for example, iron (Fe), aluminum (Al), copper (Cu), or brass). A low temperature contact part 240 may be provided on the bottom face of the pair of second conductive films 180. One face of the low temperature contact part 240 may contact the pair of second conductive films 180, and the other face may be exposed to the air or contact a cooling device (not shown). The low temperature contact part 240 may contain a thermally conductive material (for example, iron (Fe), aluminum (Al), copper (Cu), or brass).

A thermoelectric device according to an embodiment of the inventive concept may include the thermoelectric material described with reference to FIGS. 1 and 2, and thus exhibit enhanced thermoelectric performance.

FIG. 5 is a conceptual diagram illustrating a thermoelectric device according to an embodiment of the inventive concept. For conciseness of description, explanations substantially identical to those given with reference to FIG. 4 may be excluded.

Referring to FIG. 5, a thermoelectric device 1000 including a first thermoelectric element TE1 and a second thermoelectric element TE2 connected in series may be provided. The first thermoelectric element TE1 and the second thermoelectric element TE2 may be substantially identical to the thermoelectric element TE described with reference to FIG. 4. A second thermoelectric material unit 140a of the first thermoelectric element TE1 may be electrically connected to a first thermoelectric material unit 120b of the second thermoelectric element TE2 through a second conductive film 180a. Specifically, the second thermoelectric material unit 140a of the first thermoelectric element TE1 may contact a portion of the second conductive film 180a, and the first thermoelectric material unit 120b of the second thermoelectric element TE2 may contact another portion of the second conductive film 180a. The second conductive film 180a may extend from the bottom face of the second thermoelectric material unit 140a of the first thermoelectric element TE1 to the bottom face of the first thermoelectric material unit 120b of the second thermoelectric element TE2. A high temperature contact part 220 may be provided on the first and second thermoelectric elements TE1 and TE2 and cover both of the first and second thermoelectric elements TE1 and TE2. A low temperature contact part 240 may be provided between the first and second thermoelectric elements TE1 and TE2 and be provided on the reverse side of the high temperature contact part 220. The low temperature contact part 240 may cover both of the first and second thermoelectric elements TE1 and TE2. The first and second thermoelectric elements TE1 and TE2 may be connected to an electrical device Z through an electrical pathway P. One end of the electrical pathway P may be connected to the second conductive film 180b in contact with the bottom face of the first thermoelectric material unit 120a of the first thermoelectric element TE1, and the other end may be connected to the second conductive film 180c in contact with the bottom face of the second thermoelectric material unit 140b of the second thermoelectric element TE2.

A thermoelectric device according to an embodiment of the inventive concept may include the thermoelectric material described with reference to FIGS. 1 and 2 such that the thermoelectric performance is improved.

According to an embodiment of the inventive concept, a thermoelectric material having enhanced thermoelectric performance may be provided. In particular, the thermal conductivity may be minimized through silicon particles and a metal silicide film and the electrical conductivity may be maximized to thereby maximize the thermoelectric performance of the thermoelectric material.

According to an embodiment of the inventive concept, silicon (Si), which is not a heavy metal, may be used. Consequently, an environmentally friendly thermoelectric material having a reduced manufacturing cost may be provided.

However, the effects of the present invention are not limited to those disclosed above.

Although the exemplary embodiments of the present invention have been described, it is understood that the present invention should not be limited to these exemplary embodiments but various changes and modifications can be made by a person skilled in the art within the spirit and scope of the present invention as hereinafter claimed.

What is claimed is:

1. A thermoelectric element comprising:
a first thermoelectric material unit having a first conductivity type;
a second thermoelectric material unit having a second conductivity type that is different from the first conductivity type;
a first conductor contacting the top face of the first thermoelectric material unit and the top face of the second thermoelectric material unit; and
a pair of second conductors respectively contacting the bottom face of the first thermoelectric material unit and the bottom face of the second thermoelectric material unit,
wherein each of the first thermoelectric material unit and the second thermoelectric material unit contains a metal silicide film and silicon particles dispersed in the metal silicide film, the total volume of the silicon particles being greater than the volume of the metal silicide film in each of the first thermoelectric material unit and the second thermoelectric material unit.
